(19) United States
(12) Patent Application Publication
(10) Pub. No.: US 2011/0249369 A1
(43) Pub. Date: Oct. 13, 2011

(54) APPARATUS FOR PROTECTION OF ELECTRONIC CIRCUITRY AND ASSOCIATED METHODS

(76) Inventor: Timothy T. Rueger, Austin, TX (US)

(21) Appl. No.: 12/974,870

(22) Filed: Dec. 21, 2010

Related U.S. Application Data
(63) Continuation-in-part of application No. 12/954,637, filed on Nov. 25, 2010.
(60) Provisional application No. 61/323,798, filed on Apr. 13, 2010.

(51) Int. Cl. H02H 9/00; H05K 13/04

(52) U.S. Cl. 361/42; 29/825

(57) ABSTRACT

In an exemplary embodiment, an apparatus includes a single clamp circuit adapted to clamp an electrostatic discharge (ESD) voltage. The apparatus further includes a supply node coupled to the single clamp circuit via one diode, and a ground node that is coupled to the supply node via another diode. The ground node is also coupled to the single clamp circuit.

### CROSS-REFERENCE TO RELATED APPLICATIONS

This application is a continuation in part of, and incorporates by reference, U.S. patent application Ser. No. 12/954,637, filed on Nov. 25, 2010, titled “Apparatus with Optical Functionality and Associated Methods,” attorney docket number SILA301, which claims priority to, and incorporates by reference, U.S. Provisional Patent Application Ser. No. 61/323,798, filed on Apr. 13, 2010, titled “Apparatus with Optical Functionality and Associated Methods,” attorney docket number SILA300P1.

### TECHNICAL FIELD

The disclosure relates generally to apparatus for protection of electronic circuitry and, more particularly, to apparatus and associated methods for protection of electronic circuitry/systems against electrostatic discharge (ESD), over-voltage, or similar phenomena.

### BACKGROUND

Since the conception of modern electronic circuitry, such as integrated circuits (ICs), the drive to increase functionality and to reduce size and cost has continued. With virtually each generation of ICs, the devices can include more transistors in a smaller size and die area.

The decrease in the size of circuit features, for example, transistor geometries, however, makes the circuit elements and/or devices susceptible to phenomena such as ESD, over-voltage, and over-current. Such phenomena may cause damage to circuit elements and, possibly, to entire devices or systems.

FIG. 1 shows a circuit arrangement 10 for a conventional ESD protection scheme. In addition to a clamp circuit 18, circuit arrangement 10 uses diodes 12, 14, 16, 20, and 22 as part of the protection scheme. During an ESD event, input/output (I/O) pad 24 may have a high voltage relative to the voltage at I/O pad 26. Under such circumstances, a current path 28 exists from I/O pad 24, through diode 12 to the supply rail, V_{DD}, through clamp 18 to the ground rail (GND), and finally through diode 22 to I/O pad 26.

### SUMMARY

The disclosure relates generally to apparatus for protection of electronic circuitry and, more particularly, to apparatus and associated methods for protection of electronic circuitry/systems against ESD, over-voltage, over-current, or similar phenomena. In one exemplary embodiment, an apparatus includes a single clamp circuit adapted to clamp an ESD voltage. The apparatus further includes a supply node coupled to the single clamp circuit via a diode, and a ground node that is coupled to the supply node via another diode. The ground node is also coupled to the single clamp circuit.

In another exemplary embodiment, a system includes an IC that includes an ESD protection circuit. The ESD protection circuit includes a single clamp circuit coupled to a ground node of the IC. The single clamp circuit is further coupled via a pair of diodes to a supply node. The IC further includes an input/output (I/O) circuit that is coupled to the single clamp circuit via another pair of diodes.

In yet another exemplary embodiment, a method includes coupling a single clamp circuit to a supply node via a pair of diodes, and coupling the single clamp circuit to a ground node. The single clamp circuit is adapted to protect against an ESD voltage.

### BRIEF DESCRIPTION OF THE DRAWINGS

The appended drawings illustrate only exemplary embodiments and therefore should not be considered as limiting its scope. The disclosed concepts lend themselves to other equally effective embodiments. In the drawings, the same numeral designators used in more than one drawing denote the same, similar, or equivalent functionality, components, or blocks.

FIG. 1 illustrates a circuit arrangement for a conventional ESD protection scheme.

FIG. 2 depicts a circuit arrangement according to an exemplary embodiment.

FIG. 3 shows a circuit arrangement for a clamp circuit according to an exemplary embodiment.

FIG. 4 depicts a block diagram according to an exemplary embodiment for protection of an IC from ESD events.

FIG. 5 illustrates a block diagram of a circuit arrangement according to an exemplary embodiment for protection of electronic circuitry that includes a sensor IC.

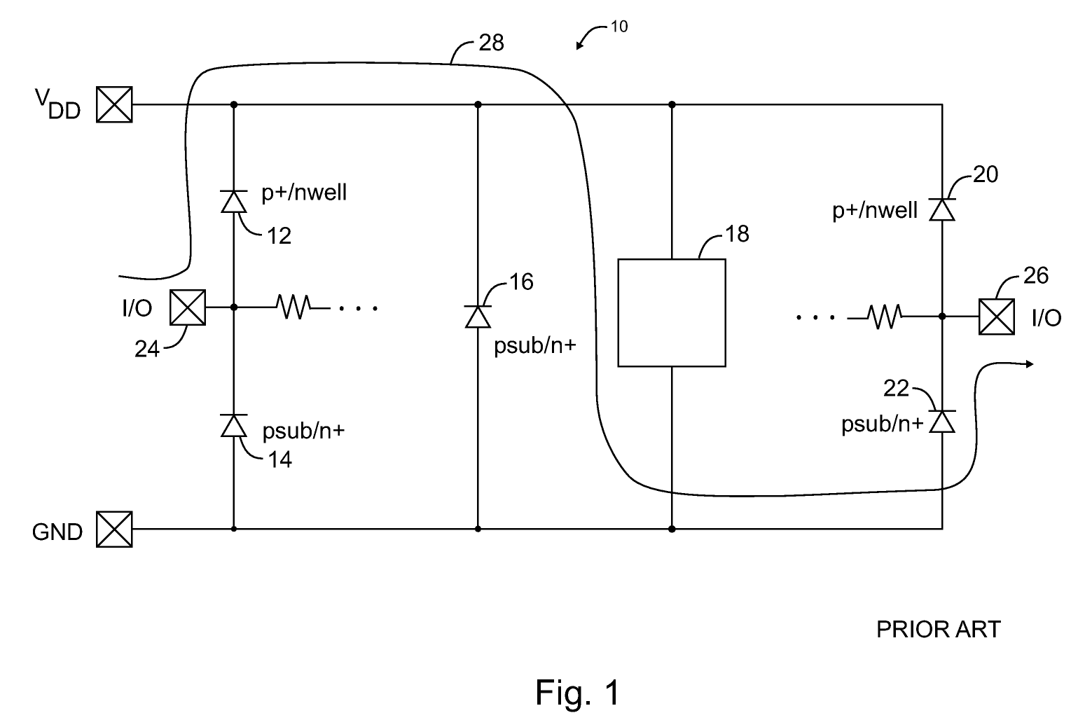

### DETAILED DESCRIPTION

The disclosed apparatus and associated methods provide protection against ESD, over-voltage, over-current, or similar phenomena, with improved circuit size/cost, and improved die efficiency in ICs. Apparatus and associated methods according to various embodiments may provide such protection in electronic circuits, systems employing such circuits, ICs, systems incorporating ICs, etc.

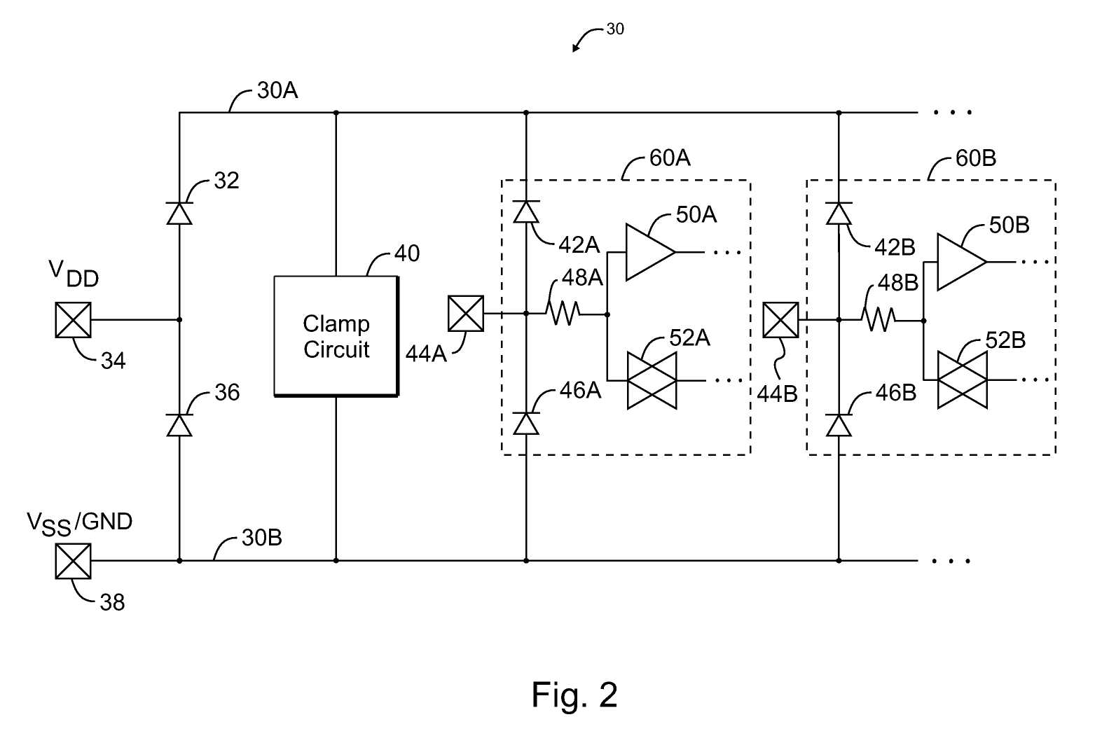

FIG. 2 depicts a circuit arrangement 30 according to an exemplary embodiment. Diode 32 couples supply voltage (V_{DD}) pad or connection 34 to a rail (generally node) 30A (e.g., internal supply rail or node of an IC). Conversely, diode 36 couples V_{DD}) pad 34 to ground (GND) pad or connection 38, which is coupled to a ground rail (generally node) 30B. Clamp circuit 40 couples to rails 30A, 30B.

Circuit arrangement 30 may include one or more sub-blocks or circuits for I/O (or circuitry associated with one or more I/O pads). In the example shown in FIG. 2, circuit arrangement 30 shows two such circuits. Specifically, I/O pad 44A couples to a corresponding I/O circuit 60A, whereas I/O pad 44B couples to a corresponding I/O circuit 60B.

Referring to FIG. 2, the following description of I/O pad 44A and associated circuitry 60A also applies to I/O pad 44B and associated circuitry 60B, if used, and/or additional pads and associated circuitry (if more than two are used). I/O pad 44A couples to rail 30A via diode 42A. Similarly, I/O pad 44A couples to rail 30B via diode 46A. Note that, rather than the implementation of diode 46A shown in FIG. 2, one may use a variety of other implementations, as desired, depending on factors such as whether the circuitry is integrated, the type of fabrication technology available, etc.

Generally, clamp circuit 40 protects against ESD events. More specifically, clamp circuit 40 can protect against ESD events at the supply (including circuit ground) pads/rails and/or I/O pads, pins, etc.

Generally speaking, ESD events can occur between any pair of pads on an IC. For example, an ESD event may occur between the supply pad, e.g., V_{DD} pad 34 and I/O pad 44A in FIG. 2. In this situation, diode 32 turns on, and conducts the resulting current through clamp circuit 40 and diode 46A, and back to pad 44A. Clamp circuit 40 clamps the voltage appearing across its terminals. As a result, the circuit provides protection against the ESD event between the supply pad and an I/O pad. Similarly, when the voltage at the supply pad 34 rises with respect to the ground pad 38, diode 32 turns on and conducts the resulting current through clamp circuit 40, providing protection against the ESD event between the supply and ground pads.

The circuit also provides protection against ESD events on the circuit ground or return pad or pin. For example, assume that the voltage at ground pad 38 rises with respect to an I/O pad, for example, I/O pad 44A, because of an ESD event. Consequently, diode 46A conducts current, which clamps the resulting voltage. Similarly, when the voltage at ground pad 38 rises with respect to supply pad 34, diode 36 conducts current, which clamps the resulting voltage.

As noted, circuit arrangement 30 also provides protection for I/O pad(s) 44A/44B or other connections. For example, assume that the voltage at I/O pad 44A rises with respect to I/O pad 44B because of an ESD event. Diode 42A conducts current through clamp circuit 40 and diode 46B, and back to pad 44B. Clamp circuit 40 clamps the voltage appearing across its terminals. As a result, the circuit provides protection against the ESD event between two I/O pads. Similarly, if the voltage at I/O pad 44A rises with respect to supply pad 34 because of an ESD event, diode 42A conducts current through clamp circuit 40 and diode 36, and back to supply pad 34. As a result, the circuit provides protection against the ESD event between and I/O pad and a supply pad. Similarly, if the voltage at I/O pad 44A rises with respect to ground pad 38 because of an ESD event, diode 42A conducts current through clamp circuit 40 and back to ground pad 38. As a result, the circuit provides protection against the ESD event between and I/O pad and a ground pad.

The disclosed scheme provides advantages in many situations, including when one or more pads are coupled to one or more externally powered buses and the power supply is turned off or disabled (e.g., as part of a power management scheme). In such a situation, current conduction from diodes 42A and/or 42B in the I/O pads through bus 30A is blocked by diode 32, which is coupled to the power supply pad. The scheme disclosed in the exemplary embodiment of FIG. 2 therefore allows the IC to be powered off or disabled without disturbing a shared externally powered bus.

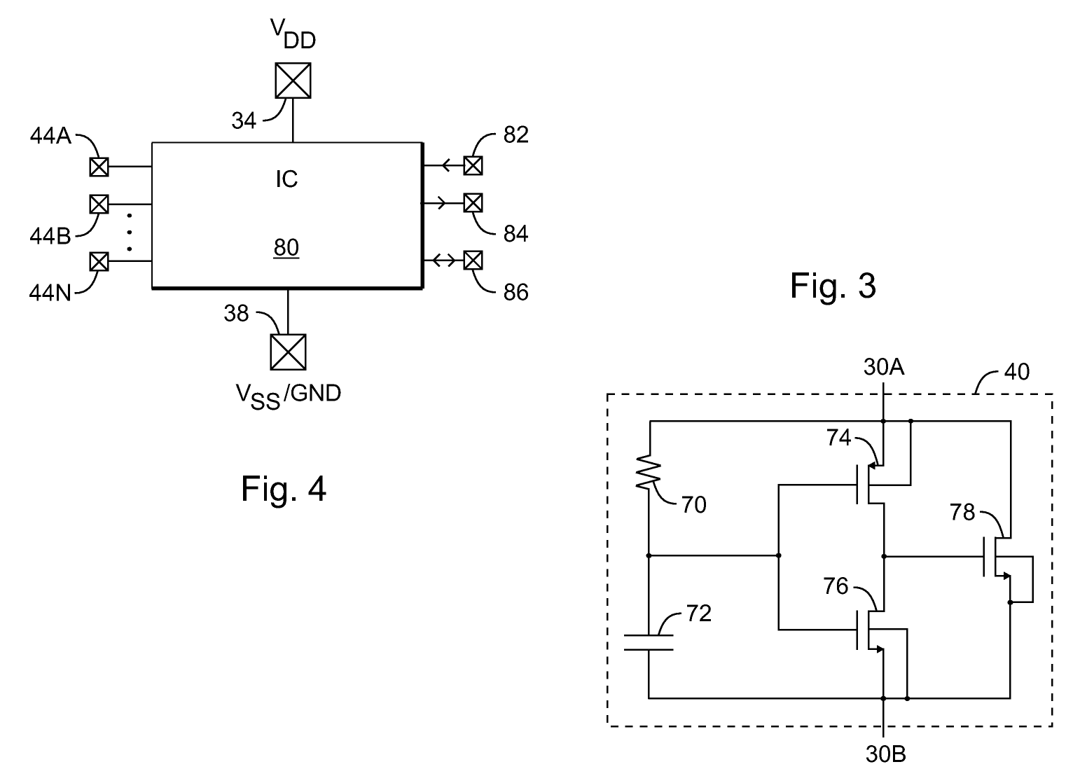

FIG. 3 shows a circuit arrangement for clamp circuit 40 according to an exemplary embodiment. Clamp circuit 40 includes resistor 70 and capacitor 72, as well as PMOS transistor 74, and NMOS transistors 76 and 78.

Resistor 70 and capacitor 72 form a timing circuit. The timing circuit drives the gates of transistor 74 and transistor 76. The drains of transistor 74 and transistor 76 drive the gate of transistor 78 (a clamping device).

Assume that that the circuit has been in a steady-state. Capacitor 72 has no charge or a constant or substantially constant voltage across it, and therefore a negligible or zero current flowing through it. In this situation, the gates of transistors 74 and 76 are pulled high (to the voltage at rail 30A or substantially to the voltage at rail 30A) via resistor 70. Accordingly, transistor 74 is off, and transistor 76 is on, pulling down the gate of transistor 78, thus turning it off. Thus, in the absence of an ESD event, transistor 78 is off, and conducts no current (or a negligible amount of current) from rail 30A to rail 30B (i.e., performs no clamping action).

Now, assume an ESD event occurs. As a result, the voltage at rail 30A rises sufficiently relative to the voltage across capacitor 72 (which cannot change instantaneously) to turn on transistor 74. Consequently, transistor 74 turns on, which causes transistor 78 to turn on, and clamp the ESD voltage present across rails 30A, 30B.

Because of the increased voltage at rail 30A, capacitor 72 charges through resistor 70. As the voltage across capacitor 72 increases, it causes the absolute value of the gate-source voltage of transistor 74 to decrease, which at some point causes transistor 74 to turn off. Once transistor 74 turns off, it causes transistor 78 to also turn off, thus ceasing the clamping action. Thus, transistor 78 (generally, clamp circuit 40) provides a clamping action across rails 30A, 30B for a period of time determined by the values of resistor 70 and capacitor 72.

As noted above, the disclosed apparatus and associated methods provide protection for supply pads/pins as well as I/O pads/pins. Note that the “I/O” designation may include any desired variety of signals input to, and output from, an electronic circuit, such as an IC. Examples include data signals, address signals, control signals, status signals, sensor/transducer input signals, sensor/transducer output signals, and the like. Thus, one may use the protection circuitry and methods disclosed herein in a wide variety of situations and with a wide variety of electronic circuitry, including analog, digital, and mixed-signal circuitry.

FIG. 4 depicts a block diagram according to an exemplary embodiment for protection of an IC 80 from ESD events. IC 80 obtains power and ground via supply pad 34 and ground pad 38, respectively. IC 80 may include the circuitry shown in FIG. 2 to provide protection for pads 34, 38 against ESD events.

Referring to FIG. 4, IC 80 may include one or more I/O pads, such as I/O pads 44A-44N. I/O pads 44A-44N may couple to one or more buses (not shown). IC 80 may include the circuitry shown in FIG. 2 to provide protection for I/O pads 44A-44N against ESD events.

Referring to FIG. 4, IC 80 may include one or more general input pads (e.g., sensor input, status input, command input, etc.) 82. IC 80 may include the circuitry shown in FIG. 2 to provide protection for input pad(s) 82 against ESD events.

Referring to FIG. 4, IC 80 may include one or more general output pads (e.g., sensor or actuator output, status output, command output, etc.) 84. IC 80 may include the circuitry shown in FIG. 2 to provide protection for output pad(s) 84 against ESD events.

Referring to FIG. 4, IC 80 may include one or more general input/output pads (e.g., sensor or actuator input/output, status input/output, command input/output, general-purpose input/output (GPIO), etc.) 86. In the embodiment shown, general input/output pads may or may not couple to one or more buses, as desired. IC 80 may include the circuitry shown in FIG. 2 to provide protection for general input/output pad(s) 86 against ESD events.

As noted, one may use the disclosed apparatus and associated methods for the protection of a wide variety of circuitry, such as ICs and, more particularly, sensor ICs. Thus, one aspect of the disclosed concepts relates to protection of sensor ICs optimized for use in various apparatus or host systems.

In some exemplary embodiments, a sensor IC may perform optical reflectance proximity, motion, and ambient light functions with high sensitivity and reduced, optimized, and/or minimal power consumption. The ambient light sensing functionality may include sensing of visible light, infrared (IR) light, or both, as desired.

In exemplary embodiments, relatively high sensitivity may be achieved by a direct coupling of the photodetectors to a delta-sigma ADC, having relatively high-resolution, via a multiplexer (MUX), and using per-measurement calibration, as desired. As described below in detail, operation with relatively low power consumption may be achieved by operating the LED drivers, ADC, and controlling circuitry at a relatively low duty cycle. Continuous power consumption in other blocks is kept to a minimum and/or relatively low or optimized level. Operating the LED drivers, ADC, and controlling circuitry at low duty cycles reduces the power dissipation in the sensor IC and, hence, a system in which the sensor IC may reside.

In exemplary embodiments, the IC provides a host processor with digital measurements of light energy as sensed by on-chip photodiodes through a transparent IC package (or off-chip sensors, as desired). In exemplary embodiments, proximity and motion are measured by illuminating one or more external infrared LEDs (e.g., the LEDs 118) and sensing the reflected infrared light. In some exemplary embodiments, ambient light is measured by sensing incident infrared and visible light and optionally applying photopic correction.

In exemplary embodiments, the host controller or processor 104 may constitute a controller, microcontroller, processor, microprocessor, field-programmable gate array (FPGA), programmable controller, or the like, as desired. In exemplary embodiments, the host processor 104 may include one or more of integrated RAM (including program RAM, as desired), ROM, flash memory (or non-volatile memory generally), one-time programmable (OTP) circuitry, analog-to-digital converters (ADCs), digital-to-analog-converters (DACs), counters, timers, input/output (I/O) circuitry and controllers, reference circuitry, clock and timing circuitry (including distribution circuitry), arithmetic circuitry (e.g., adders, subtracters, multipliers, dividers), general and programmable logic circuitry, power regulators, and the like, as desired. Integrating one or more of the circuitry described above can improve the overall performance in some applications, for example, flexibility, responsiveness, die area, cost, materials used, power consumption, reliability, robustness, and the like, as desired.

In some embodiments, the host processor or controller and the sensor IC (including some or all of the blocks of circuitry described in this document, for example, photodiodes or detectors) may be integrated within one IC or device, as desired. In some embodiments, the host processor and the sensor IC may be integrated within a single semiconductor die, as desired. The integration of the host processor and the sensor IC (whether on a single die, within a multi-chip module (MCM), etc.) may provide advantages in some applications, for example, higher speed, lower cost, etc.

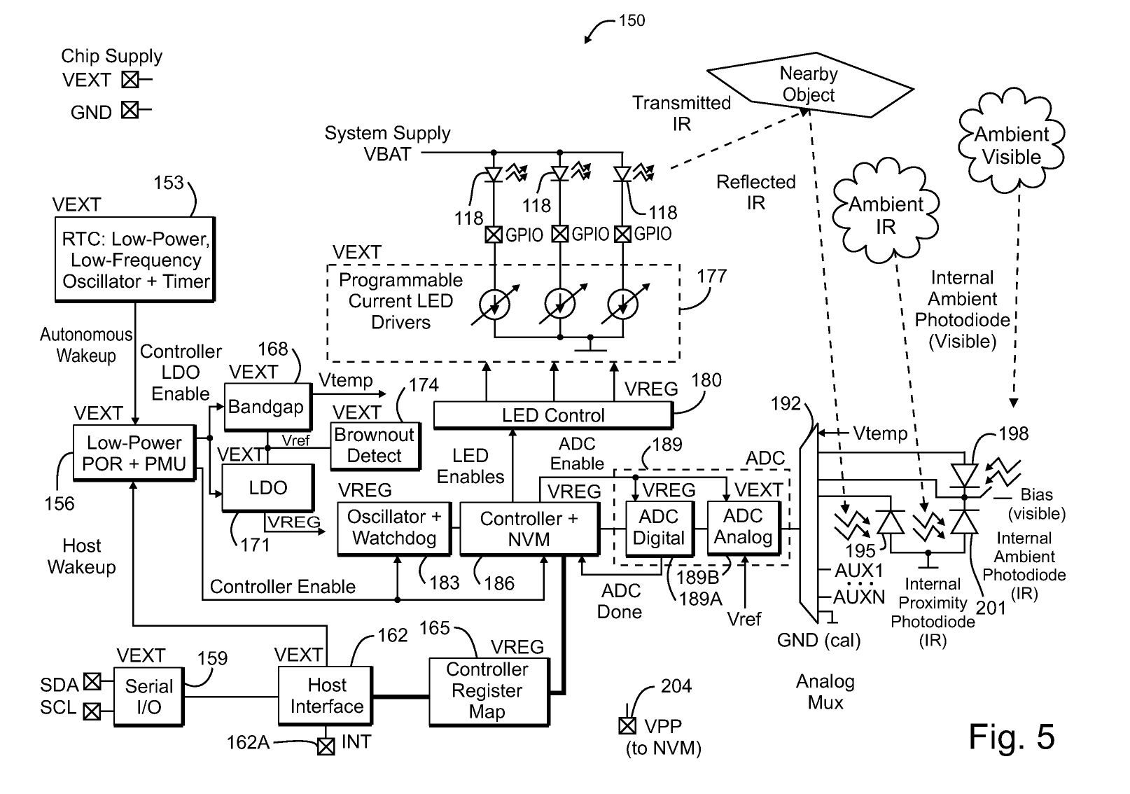

FIG. 5 illustrates a circuit arrangement 150 according to an exemplary embodiment for protection against ESD events of a sensor IC. In the embodiment shown, the sensor IC includes the following blocks or circuitry: Power-on Reset (POR) 156, Power Management Unit (PMU) 156, Real-Time Clock (RTC) 153, serial I/O 159, host interface 162, bandgap reference 168, digital low-drop-out (LDO) regulator or circuit 171, brownout detector 174, oscillator with watchdog timer 183, controller 186 (including, as desired, non-volatile memory (NVM)), register map 165, output control 180, GPIOs with programmable fixed-current drivers 177, photodetectors 195, 198, and 201 (which may be internal, i.e., integrated, or external, as desired), analog MUX 192, ADC 189, and other I/O pins (e.g., interrupt pin 162A for host interface 162).

Photodetector 195 detects or senses light, for example, infrared light in order to determine proximity of a nearby object. Photodetector 198 detects or senses light, for example, ambient visible light. Photodetector 201 detects or senses light, for example, ambient infrared light.

On initial power up, the POR circuit 156 holds the sensor IC in reset until a safe level for the supply voltage is attained. Once the POR is released, the PMU circuit 156 (shown as part of the POR circuit 156) starts the bandgap reference 168 and the digital core LDO 171, waiting until after the LDO level is settled before starting the oscillator 183 and the controller 186. After chip initialization, the controller 186 signals PMU 156 to put the sensor IC into sleep mode (to reduce power consumption). Note that, depending on application, the PMU 156 may not place the sensor IC into sleep mode (cause the sensor IC to enter the sleep mode), as desired.

In one exemplary embodiment, for on-demand operation(s), the PMU 156 wakes up the sensor IC (or other circuitry in the sensor IC) upon receiving a wake-up signal from the host interface 162. After waking up, the controller 186 decodes the incoming host command and performs the requested operation(s).

In one exemplary embodiment, in autonomous mode, the PMU 156 wakes up the sensor IC after receiving a signal from an internal programmable timer, and performs operation(s) autonomously as previously specified by the host (not shown explicitly).

After an operation is completed, the controller 186 signals the PMU 156 to put the sensor IC into sleep mode until the next operation. This power-management scheme conserves power by shutting down high-power blocks when their functions are not needed or used.

Since in exemplary embodiments it is powered continuously, analog circuitry inside the PMU 156 is designed using relatively low-power biasing to reduce or minimize power consumption, given that, in typical applications, the IC spends the most time in sleep mode.

A low-power, low-frequency on-chip oscillator 153 is used to clock a timer (shown as part of oscillator 153). The timer is programmable by the host processor (not shown explicitly) to control the rate of light measurements in autonomous mode. The oscillator 153 uses relatively low-power biasing to minimize power consumption. In applications where the sensor IC spends most of the time (or a relatively large percentage of the time) in sleep mode, this property is desirable as it reduces power consumption. The oscillator 153 may be calibrated to reduce or minimize the effects of semiconductor fabrication process variations on its output frequency.

A serial input/output interface 159 is used to communicate with the host processor (not shown explicitly) over a serial protocol, such as I2C or SMB although one may use other types of protocol depending on factors such as given specifications or intended applications. In one such serial protocol, one line is used as a clock (SCL), while another is a bidirectional data line (SDA). These are used to send control information or read light measurements or status to/from the sensor IC.

In exemplary embodiments, the serial clock, serial data, and interrupt I/O structures are designed to allow the sensor IC 112 to be powered down while not loading the shared data lines in the host system. Similarly, the LED I/O structures allow sensor IC 112 to be powered down while not drawing current from the shared or independent LED power supply. This allows the sensor IC 112 to be powered from a host processor I/O pin, thus simplifying system power management and reducing system cost.

The host interface 162 connects the serial I/O block to the internal controller 186 via the controller register map 165. The controller register map 165 contains control registers, parameters, and measured data. Some registers are shared with the internal controller 186. Upon receipt of an appropriate command from the host, the host interface 162 sends a wakeup signal to the PMU 156 to initiate an on-demand light reading. The host interface 162 also controls an interrupt pin 162A for alerting the host processor when a light reading is available, when a light reading exceeds a prescribed threshold, or other events, as desired.

In the exemplary embodiment shown in FIG. 5, the sensor IC has process and convert modes. In those modes, the LDO regulator 171 powers the high-speed oscillator 183, the controller 186, and the ADC digital circuitry 189A. In sleep mode, the LDO 171 is powered down by the PMU 156. During this mode, the controller and register map states are maintained by the use of data retention flip-flops (not shown explicitly) that use the external power supply to latch their held values.

The brownout detection circuit 174 provides a failsafe for drops in the sensor IC's external voltage supply. It compares the supply level (or a scaled version of it) to the bandgap reference voltage from bandgap circuit 168, and signals the PMU 156 when the supply falls below a specified level. The brownout detection voltage level may be calibrated to minimize the effect of semiconductor fabrication process variations.

The high-speed on-chip oscillator 183, powered by the LDO regulator 171, is used to clock the controller 186 and the ADC 189. In the process mode of the sensor IC, the oscillator 183 clocks the controller 186. In the convert mode, the oscillator 183 clocks the ADC 189, while processing by the controller 186 is suspended. In the sleep mode, the oscillator 183 is powered down with the rest of the digital blocks powered from the digital LDO 171. The oscillator 183 may be calibrated to minimize the effect of semiconductor fabrication process variations on its output frequency.

A watchdog timer (shown as part of the oscillator 183) may be included to monitor transitions on the output of the oscillator 183. If a predetermined amount of time passes without a clock edge, a clock failure signal may be sent to the PMU 156 for handling of the clock failure. In some embodiments, the watchdog timer may generate a reset signal for the sensor IC under these or other desired circumstances.

In exemplary embodiments, the controller 186 constitutes a flexible programmable controller, used to coordinate the operations of the various blocks of the sensor IC. In exemplary embodiments, it receives commands from the host interface 162, configures and enables the GPIOs, configures the ADC 189 and the analog MUX 192, controls the ADC 189, receives data from the ADC 189, and sends data to the host interface 162. In exemplary embodiments, controller 186 uses analog MUX 192 to select among any photodetectors on sensor IC 112, auxiliary internal or external signals, or external sensors via dedicated I/Os. A zero-signal input may be selected for purpose of per-reading calibration. The temperature voltage output from the bandgap reference circuit (described below in detail) may also be selected for digitizing the temperature.

ADC 189 is used to convert the level or intensity of incident light to a digital word for on-chip and host processing. In exemplary embodiments, ADC 189 is a current-input incremental-mode second-order delta-sigma modulator. The 1-bit data output stream is double-integrated to provide an output code proportional to the incoming light level.

In exemplary embodiments, the controller 186 may constitute a controller, microcontroller, processor, microprocessor, field-programmable gate array (FPGA), programmable controller, or the like, as desired. In exemplary embodiments, the controller 186 may include one or more of integrated RAM (including program RAM, as desired), ROM, flash memory (or non-volatile memory generally), one-time programmable (OTP) circuitry, analog-to-digital converters (ADCs), digital-to-analog-converters (DACs), counters, timers, input/output (I/O) circuitry and controllers, reference circuitry, clock and timing circuitry (including distribution circuitry), arithmetic circuitry (e.g., adders, subtracters, multipliers, dividers), general and programmable logic circuitry, power regulators, and the like, as desired.

In exemplary embodiments, program software is stored in nonvolatile memory (NVM). In exemplary embodiments, the NVM is designed to be immune or substantially immune to ambient light by using a dedicated light shield, for example, a metal shield). Ambient light effects on the sensor IC (except the photodetectors) should be minimized or reduced, given that the sensor IC is packaged in a light-transparent encapsulation.

When operating in the process mode, the controller 186 functions according to its stored program. Integrating one or more of the circuitry described above can improve the overall performance in some applications, for example, flexibility, responsiveness, die area, cost, materials used, power consumption, reliability, robustness, and the like, as desired.

The controller 186 provides different functionality depending on the mode of operation of the sensor IC. In the convert mode, the controller clock is interrupted while the ADC 189 performs analog-to-digital conversion of the incoming light signal. This scheme both conserves power and provides a quieter environment (from a noise and/or EMI/EMC point-of-view) for precision analog-to-digital conversion. The controller clock is restarted after the ADC operation is completed. In the sleep mode, the controller 186 is powered down to conserve power. Controller state is maintained by the use of data retention flip-flops (not shown explicitly) that use the external power supply to latch their held values, as described above.

The register map 165 contains status, control, and data for the sensor IC. Some register values are shared with the host interface 162 to transfer commands and data to or from the host interface 162. In the sleep mode, register map state is maintained by the use of data retention flip-flops that use the external power supply to latch their held values. In the sleep mode, register map state is maintained by the use of data retention flip-flops (not shown explicitly) that use the external power supply to latch their held values.

The output block 180, labeled as “LED control” in FIG. 5, interfaces the controller 186 to the GPIO drivers (or LED drivers) 177. Depending on the requested function, the output control block 180 configures and powers up the output drivers 177 with the prescribed current level. The output control is flexible, and allows using any combination of output drivers sequentially or simultaneously for measurement, as desired. The output driver(s) 177 may be independently controlled for different current levels, as desired.

In exemplary embodiments, a separate pin 204 may be used to provide the relatively high programming voltage (labeled “VPP”) used by the NVM during manufacturing. It may not be coupled or used in the end system or user application. In other exemplary embodiments, this functionality may be realized using a shared pin and internal multiplexing, as desired.

As noted, sensor ICs according to exemplary embodiments may include one or more bandgap voltage and/or current reference circuits. In an exemplary embodiment, the sensor IC includes a temperature-compensated voltage reference, a temperature-compensated current reference, and a temperature sensor.

In other embodiments, one may omit one or more of the foregoing items. For example, in some embodiments, the sensor IC may omit the temperature-compensated voltage reference or the temperature-compensated current reference. If included, the voltage reference is used to set the output voltage of the digital LDO, the full-scale level of the ADC, and the trip level of the brownout detector. The voltage reference may be calibrated to minimize the effect of semiconductor fabrication process variations.

The current reference provides bias currents to the ADC and the LED drivers. In exemplary embodiments, the current reference is implemented in a relatively area-efficient manner that can also provide temperature compensation, as desired. A temperature sensor provides a voltage that is proportional to absolute temperature. This voltage may be digitized by the ADC to provide either temperature readings to the host or provide for temperature correction of photodetector measurements. To save power, the temperature sensor may be disabled by the host, as desired.

As noted, sensor ICs according to exemplary embodiments may include one or more GPIOs. The GPIOs may provide a variety of functions, for example, couple programmable fixed-current driver(s) to power external LED(s) used primarily for proximity detection or measurement, and the like. Generally, in some embodiments, the LED driver pin of the optical IC may be reconfigured as a general purpose input/output to enable other system functions. The different operating modes are enabled or disabled by bit controls from control registers, e.g., control register map 165.

The LED current level(s) is (are) programmable to provide illumination levels for different detection or measurement ranges. In one exemplary embodiment, up to three LEDs may be driven, depending on the complexity of proximity or motion detection/measurement being performed. One may use different numbers of LEDs, however, as desired, by making appropriate changes. Those changes fall within the knowledge and skill of persons of ordinary skill in the art.

The system battery potential may exceed the maximum voltage in the chosen IC semiconductor fabrication process technology. In an exemplary embodiment, the LED drivers are designed to tolerate this voltage level when the LEDs are turned off. This feature prevents damage to the IC when the LEDs are powered off and the LED package pins are pulled up by the system battery or supply source.

The large current source driver transistors used for LED illumination are also used to absorb electrostatic discharge (ESD) energy. A dv/dt sensor (a sensor for sensing the rate of change of voltage as a function of time) on one or more LED pin senses the voltage ramp on the pin, and turns on the output driver transistor during an ESD event. While in the on state, the driver device limits the voltage on the pin, thus preventing damage to circuitry within the sensor IC and/or system. In exemplary embodiments, the current output ramp rate is also controlled to limit inductive voltage drops (for example, because of parasitic inductance) and radiated electromagnetic energy.

In one exemplary embodiment, the LED drivers are also designed to enable analog and digital I/O on the same package pins. This feature enables nonvolatile memory programming access as well as debug and manufacturing test access. It also enables additional system-level functions described herein.

In exemplary embodiments, GPIOs may provide supplemental I/O functionality or modes. For example, in some embodiments, the principal I/O function, for example, LED driver output, is multiplexed with supplemental functions, such as a bidirectional current/voltage source, DAC output, ADC input, and implemented with the same I/O pin. In a typical application, the LED output is active during a limited period of time and is inactive otherwise. It is therefore possible to reconfigure and use the LED GPIO(s) for other functionality.

In one embodiment, a plurality of LED driver I/Os are used. Some of the driver I/Os may be re-configured to perform other functions as their primary purpose, or vary depending on the NVM code or external conditions (for example, automatic detection of the presence of LED(s), external sensor input, servo control output).

The supplemental analog I/O mode function allows interfacing external sensors or electrical quantities (for example, voltage, charge, current) to the internal ADC to perform other measurements (for example, humidity, passive infrared (PIR), temperature, light, and capacitance). In combination with the flexibility of NVM programming, various types of sensors may be realized by the sensor IC, as desired.

The external pin configuration (e.g., type of sensor, attached device digital ID, or measured electrical quantity) may be detected by the controller (e.g., controller 186 in the embodiment shown in FIG. 5) and the controller can execute code stored in the NVM specific to a momentary external configuration. An LED driver pin may output programmable current and voltage in two polarities. In exemplary embodiments, it is also possible to operate the LED driver simultaneously in a combination of functional modes (for example, an LED current can be turned on with the analog input active so the pin voltage can be measured internally by the ADC).

As noted, in exemplary embodiments, the serial clock, serial data, and interrupt I/O structures are designed to allow the sensor IC to be powered down while not loading the shared data lines in the host system. Similarly, the LED I/O structures allow the IC to be powered down while not drawing current from the LED power supply. This allows the sensor IC to be powered from a host processor I/O pin, which simplifies system power management and reduces system cost.

The disclosed protection apparatus and associated methods may be advantageously used in this scheme. For example, one may use the circuit arrangement shown in FIGS. 2-4 to implement protection against ESD events.

Generally speaking, one may use the protection schemes described above to any pin or pad (or generally node) in the circuit arrangement of FIG. 5, as desired, by adding appropriate circuitry (e.g., as shown in FIG. 2). Without limitation, one may apply such a protection scheme to the pads/pins shown in FIG. 5 (or others not shown), such as the GPIO pins/pads, the serial interface pins/pads, and to the supply (VEXT, GND, VPP) pins/pads.

As persons of ordinary skill in the art understand, one may use the ESD protection scheme according to the disclosed concepts in a variety of circuits or systems that use sensor ICs, as desired. For example, the ESD protection schemes disclosed are applicable to any system that uses similar power management schemes.

Referring to the figures, note that the various blocks shown might depict mainly the conceptual functions and signal flow. The actual circuit implementation might or might not contain separately identifiable hardware for the various functional blocks and might or might not use the particular circuitry shown. For example, one may combine the functionality of various blocks into one circuit block, as desired. Furthermore, one may realize the functionality of a single block in several circuit blocks, as desired. The choice of circuit implementation depends on various factors, such as particular design and performance specifications for a given implementation. Other modifications and alternative embodiments in addition to those described here will be apparent to persons of ordinary skill in the art who have the benefit of this disclosure. Accordingly, this description teaches those skilled in the art the manner of carrying out the disclosed concepts, and is to be construed as illustrative only.

The forms and embodiments shown and described should be taken as illustrative embodiments. Persons skilled in the art may make various changes in the shape, size and arrangement of parts without departing from the scope of the disclosed concepts in this document. For example, persons skilled in the art may substitute equivalent elements for the elements illustrated and described here. Moreover, persons skilled in the art may use certain features of the disclosed concepts independently of the use of other features, without departing from the scope of the disclosed concepts.

1. An apparatus, comprising:
a single clamp circuit adapted to clamp an electrostatic discharge (ESD) voltage;
a supply node coupled to the single clamp circuit via a first diode; and
a ground node coupled to the supply node via a second diode, the ground node further coupled to the single clamp circuit.

2. The apparatus according to claim 1, wherein the supply node comprises a supply pad.

3. The apparatus according to claim 1, wherein the ground node comprises a supply ground pad.

4. The apparatus according to claim 1, further comprising an input/output (I/O) circuit coupled to the single clamp circuit.

5. The apparatus according to claim 4, wherein the input/output (I/O) circuit is coupled to the single clamp circuit via a pair of diodes.

6. The apparatus according to claim 5, wherein the input/output (I/O) circuit is coupled to an inverter.

7. The apparatus according to claim 5, wherein the input/output (I/O) circuit is coupled to a transmission gate.

8. The apparatus according to claim 1, wherein the single clamp circuit comprises a timing circuit.

9. The apparatus according to claim 8, wherein the timing circuit comprises a resistor coupled to a capacitor.

10. The apparatus according to claim 8, wherein the timing circuit is coupled to a driver circuit.

11. The apparatus according to claim 10, wherein the driver circuit couples to, and drives, a clamping device.

12. The apparatus according to claim 11, wherein the clamping device comprises a transistor.

13. A system, comprising:
an integrated circuit (IC), comprising:
an electrostatic discharge (ESD) protection circuit comprising a single clamp circuit coupled to a ground node of the integrated circuit (IC), the single clamp circuit further coupled via first and second diodes to a supply node; and
an input/output (I/O) circuit coupled to the single clamp circuit via third and fourth diodes.

14. The system according to claim 13, wherein the input/output (I/O) circuit is coupled to a bus.

15. The system according to claim 13, wherein the input/output (I/O) circuit comprises general purpose input/output (GPIO) circuitry.

16. The system according to claim 13, wherein a first terminal of the input/output (I/O) circuit is coupled to a first terminal of the single clamp circuit via the third diode.

17. The system according to claim 13, wherein a second terminal of the input/output (I/O) circuit is coupled to a second terminal of the single clamp circuit via the fourth diode.

18. A method, comprising:
coupling a single clamp circuit to a supply node via first and second diodes;
coupling the single clamp circuit to a ground node,
wherein the single clamp circuit is adapted to protect against an electrostatic discharge (ESD) voltage.

19. The method according to claim 18, further comprising fabricating the single clamp circuit by coupling a timing circuit to a clamping device.

20. The method according to claim 19, wherein fabricating the single clamp circuit further comprises coupling the timing circuit to the clamping device via a driver circuit.
